(19) United States
(12) Patent Application Publication
(10) Pub. No.: US 2024/0047473 A1
(43) Pub. Date: Feb. 8, 2024

(54) STRETCHABLE DISPLAY DEVICE

(71) Applicant: Samsung Display Co., LTD., Yongin-si (KR)

(72) Inventors: Jin Woo CHOI, Yongin-si (KR); Min Woo KIM, Yongin-si (KR); Sung Chan JO, Yongin-si (KR); Eun A YANG, Yongin-si (KR); Jong Ho HONG, Yongin-si (KR)

(21) Appl. No.: 18/356,155

(22) Filed: Jul. 20, 2023

(30) Foreign Application Priority Data
Aug. 4, 2022 (KR) 10-2022-0097331

(51) Int. Cl. H01L 27/12; H01L 25/16; H01L 33/62; G02F 1/167; G02F 1/16766

(52) U.S. Cl. CPC H01L 27/124; H01L 25/167; H01L 33/62; G02F 1/167; G02F 1/16766

(57) ABSTRACT

Provided is a stretchable display device. The stretchable display device according to one or more embodiments of the present disclosure includes a substrate including a first island pattern, a second island pattern, and a bridge pattern connecting the first island pattern and the second island pattern, a first pixel electrode above the first island pattern, and having an area that is greater than an area of the first island pattern, a second pixel electrode above the second island pattern, a display layer above the first pixel electrode and the second pixel electrode, and configured to display an image, and a common electrode above the display layer.

### CROSS-REFERENCE TO RELATED APPLICATION

This application claims priority to, and the benefit of, Korean Patent Application No. 10-2022-0097331 filed on Aug. 4, 2022, in the Korean Intellectual Property Office (KIPO), the entire contents of both of which are incorporated by reference herein.

### BACKGROUND

### 1. Field

The present disclosure relates to a stretchable display device.

### 2. Description of the Related Art

As the information society develops, the demand for a display device for displaying an image is increasing in various forms. For example, the display device is applied to various electronic devices, such as a smart phone, a digital camera, a notebook computer, a navigation system, and a smart television.

The display device may be a flat panel display device, such as a liquid crystal display device, a field emission display device, or a light-emitting display device. The light-emitting display device includes an organic light-emitting device including an organic light-emitting element, an inorganic light-emitting device including an inorganic light-emitting element, such as an inorganic semiconductor, and a micro light-emitting device including a micro light-emitting element. Recently, the light-emitting display device has been developed as a display device stretchable vertically and/or horizontally.

### SUMMARY

Aspects of embodiments of the present disclosure provide a stretchable display device including light-emitting diode elements.

Other aspects of embodiments of the present disclosure provide a stretchable display device including a plurality of microcapsules having electrophoretic particles.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate including a first island pattern, a second island pattern, and a bridge pattern connecting the first island pattern and the second island pattern, a first pixel electrode above the first island pattern, and having an area that is greater than an area of the first island pattern, a second pixel electrode above the second island pattern, a display layer above the first pixel electrode and the second pixel electrode, and configured to display an image, and a common electrode above the display layer.

The first pixel electrode may be above a portion of the bridge pattern.

The second pixel electrode may be above another portion of the bridge pattern.

The first pixel electrode, the second pixel electrode, and the common electrode may include carbon nanotubes, carbon nanoballs, or silver nanowires.

The display device may further include a partition wall between the first pixel electrode and the second pixel electrode.

The partition wall may overlap the bridge pattern, and might not overlap the first pixel electrode and the second pixel electrode.

The first pixel electrode may overlap the bridge pattern, and the second pixel electrode might not overlap the bridge pattern.

Each of the first pixel electrode and the second pixel electrode may have a hexagonal shape in plan view.

The display layer may include microcapsules including at least two electrophoretic particles, some of the microcapsules being above the first pixel electrode, and others of the microcapsules being above the second pixel electrode.

At least one of the some of the microcapsules may overlap the first island pattern or the bridge pattern.

At least one of the others of the microcapsules may overlap the second island pattern or the bridge pattern.

The display layer may include light-emitting diode elements, some of the light-emitting diode elements being above the first pixel electrode, and others of the light-emitting diode elements being above the second pixel electrode.

At least one of the some of the light-emitting diode elements may overlap the first island pattern or the bridge pattern.

At least one of the others of the light-emitting diode elements may overlap the second island pattern or the bridge pattern.

According to one or more embodiments of the present disclosure, there is provided a display device including a substrate including island patterns, and a bridge pattern connecting adjacent ones of the island patterns that are adjacent to each other in a first direction, a pixel electrode above one of the island patterns, a display layer above the pixel electrode, and configured to display an image, and a common electrode above the display layer, and including a same material as the pixel electrode.

The display layer may include microcapsules above the pixel electrode, and including at least two electrophoretic particles.

The display layer may include light-emitting diode elements, wherein a first electrode of any one of the light-emitting diode elements is connected to the pixel electrode, and wherein a second electrode of each of the light-emitting diode elements is connected to the common electrode.

An area of the pixel electrode may be larger than an area of the one of the island patterns.

The display device may further include a signal line above the island patterns and the bridge pattern, and having a modulus that is less than a modulus of the pixel electrode.

The display device may further include a signal line above the island patterns and the bridge pattern, and having a modulus that is less than a modulus of the common electrode.

According to the aforementioned and other embodiments of the present disclosure, a thin-film transistor substrate includes a plurality of island patterns and a plurality of bridge patterns to be stretchable, at the same time, a plurality of pixel electrodes and a common electrode are formed as stretchable electrodes including carbon nanotubes, carbon nanoballs, or silver nanowires, and a display layer includes microcapsules containing stretchable gelatin as an electrolyte. Accordingly, because the thin-film transistor substrate, the plurality of pixel electrodes, the display layer, and the common electrode are all stretchable, the display area of the display device may be suitably stretched by an external force.

### BRIEF DESCRIPTION OF THE DRAWINGS

The above and other embodiments and features of the present disclosure will become more apparent by describing embodiments thereof with reference to the attached drawings, in which:

FIGS. 1 to 3 are perspective views illustrating stretchable display devices according to one or more embodiments;

FIG. 4 is an exploded perspective view illustrating a portion of a display area of a stretchable display device according to one or more embodiments;

FIG. 5A is a layout diagram illustrating an example of island patterns and bridge patterns of FIG. 4;

FIG. 5B is an enlarged layout diagram illustrating in detail area A of FIG. 5A;

FIG. 6 is a layout diagram illustrating an example of island patterns, bridge patterns, pixel electrodes, and partition walls of FIG. 4;

FIG. 7 is a layout diagram illustrating an example of island patterns, bridge patterns, pixel electrodes, partition walls, and microcapsules of a display layer of FIG. 4;

FIG. 8 is a cross-sectional view illustrating an example of a display device taken along the line A-A′ of FIG. 5B;

FIG. 9 is a layout diagram illustrating an example of island patterns, bridge patterns, and pixel electrodes of FIG. 4;

FIG. 10 is a layout diagram illustrating an example of island patterns, bridge patterns, pixel electrodes, and microcapsules of a display layer of FIG. 9;

FIG. 11 is an exploded perspective view illustrating a stretchable display device according to one or more embodiments;

FIG. 12 is a layout diagram illustrating an example of island patterns, bridge patterns, pixel electrodes, partition walls, and light-emitting devices of FIG. 11;

FIG. 13 is a cross-sectional view illustrating an example of a display device taken along the line A-A′ of FIG. 5B;

FIG. 14 is a layout diagram illustrating an example of island patterns, bridge patterns, pixel electrodes, and light-emitting elements of FIG. 11;

The (a) to (c) of FIG. 15 are views illustrating a curved surface to which a stretchable display device may be applicable according to one or more embodiments;

FIGS. 16A and 16B are views illustrating the interior of a vehicle to which a stretchable display device is applied according to one or more embodiments;

The (a) to (f) of FIG. 17 are views illustrating an exterior of a vehicle to which a stretchable display device is applied according to one or more embodiments;

The (a) to (f) of FIG. 18 are views illustrating a rear surface of a smartphone to which a stretchable display device is applied according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” may include A, B, or A and B. As used herein, the term “and/or” includes any and all combinations of one or more of the associated listed items. For example, the expression, such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

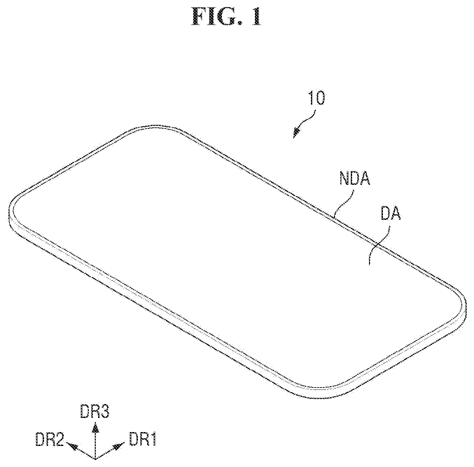

FIGS. 1 to 3 are perspective views illustrating stretchable display devices according to one or more embodiments.

Referring to FIGS. 1 to 3, a display device 10 is a device for displaying a moving image or a still image. The display device 10 may be used as a display screen of various products, such as televisions, laptop computers, monitors, billboards and the Internet of Things (IOT) device as well as portable electronic devices, such as mobile phones, smart phones, tablet personal computer (tablet PC), smart watches, watch phones, mobile communication terminals, electronic notebooks, electronic books, portable multimedia players (PMPs), navigation systems and ultra-mobile PCs (UMPCs).

The display device 10 may be a micro light-emitting diode display including a micro or nano light-emitting diode (micro-LED or nano-LED) or an electrophoretic display device including microcapsules to display an image.

The display device 10 may have a short side in the first direction DR1, and a long side in the second direction DR2 crossing the first direction DR1. Besides, a third direction DR3 may be a thickness direction of the display device 10. A corner where the short side of the first direction DR1 and the long side of the second direction DR2 meet may be rounded by having a curvature, but the present disclosure is not limited thereto. Corners of the display device 10 may be formed at right angles. The planar shape of a display device 10 may have a shape similar to a quadrangle, but the present disclosure is not limited thereto, and may be formed in a shape similar to other polygons, a circle or an oval. The display device 10 may be formed to be flat, but is not limited thereto.

The display device 10 may include a display area DA for displaying an image, and a non-display area NDA not displaying an image. The display area DA may occupy most of the area of the display device 10. The display area DA may be located in the center of the display device 10. The non-display area NDA may be located adjacent to the display area DA. The non-display area NDA may be located to surround the display area DA. The non-display area NDA may be an edge area of the display device 10.

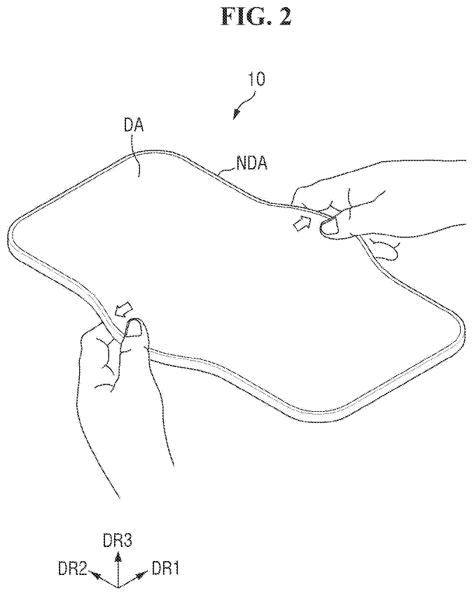

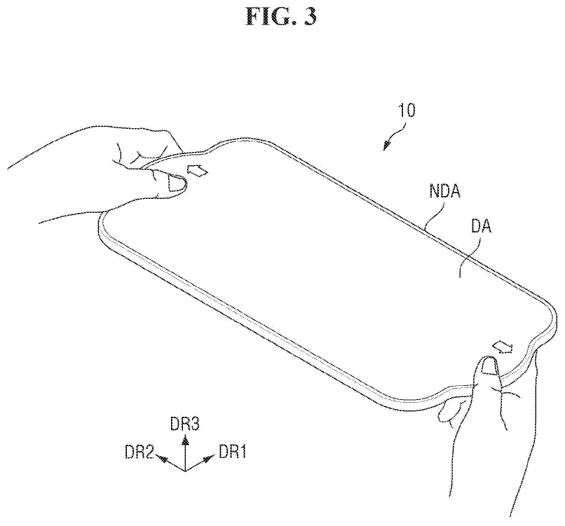

FIGS. 2 and 3 show an example of the stretchable display device 10. FIG. 2 illustrates a display device 10 that may be stretched in the first direction DR1. FIG. 3 illustrates a display device 10 that may be stretched in the second direction DR2.

Referring to FIG. 2, if the left side of the display device 10 is stretched in the left direction by holding it with one hand, and the right side of the display device 10 is stretched in the right direction by holding it with the other hand, the display device 10 may be stretched in the first direction DR1. When the display device 10 is stretched in the first direction DR1, the maximum length of the display area DA in the first direction DR1 may increase. That is, when the display device 10 is stretched in the first direction DR1, the area of the display area DA may increase.

Referring to FIG. 3, if the upper side of the stretchable display device 10 is stretched in the upper direction by holding it with one hand, and the lower side of the display device 10 is stretched in the downward direction by holding it with the other hand, the display device 10 may be stretched in the second direction DR2. When the stretchable display device 10 is stretched in the second direction DR2, the maximum length of the display area DA in the second direction DR2 may increase. That is, when the stretchable display device 10 is stretched in the second direction DR2, the area of the display area DA may increase.

In summary, the display device 10 is stretched by an external force, and it may contract and return to an original state when the external force is removed. FIGS. 2 and 3 illustrate that the stretchable display device 10 is stretched in the first direction DR1 and the second direction DR2, but the present disclosure is not limited thereto. The stretchable display device 10 may be stretched in a diagonal direction between the first direction DR1 and the second direction DR2.

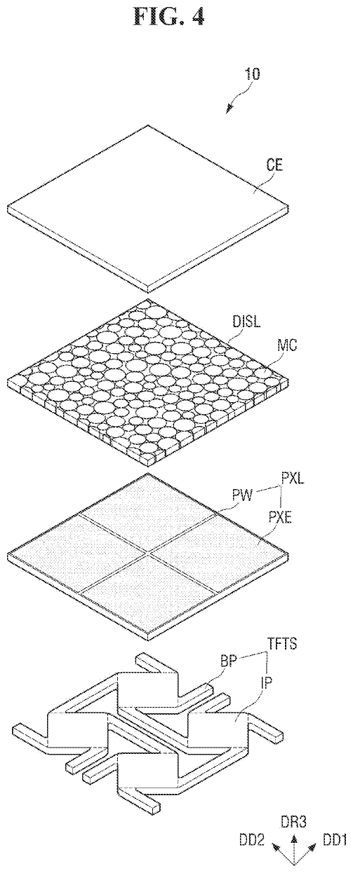

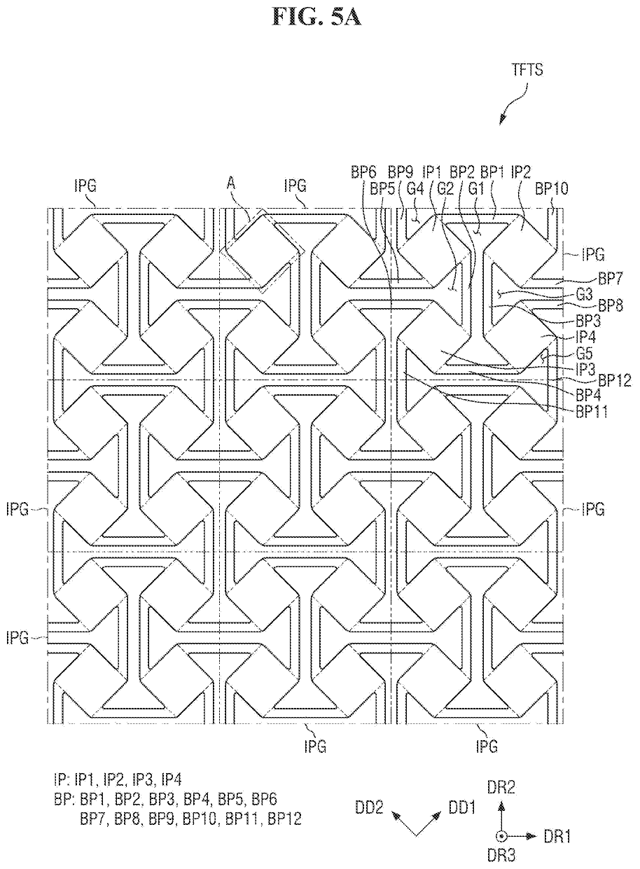

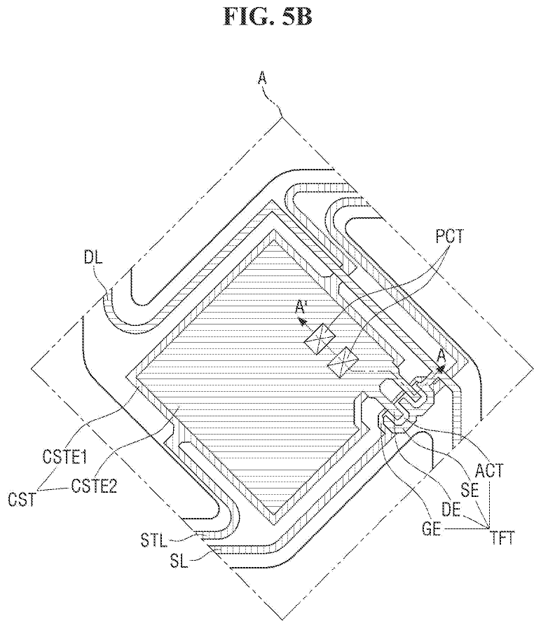

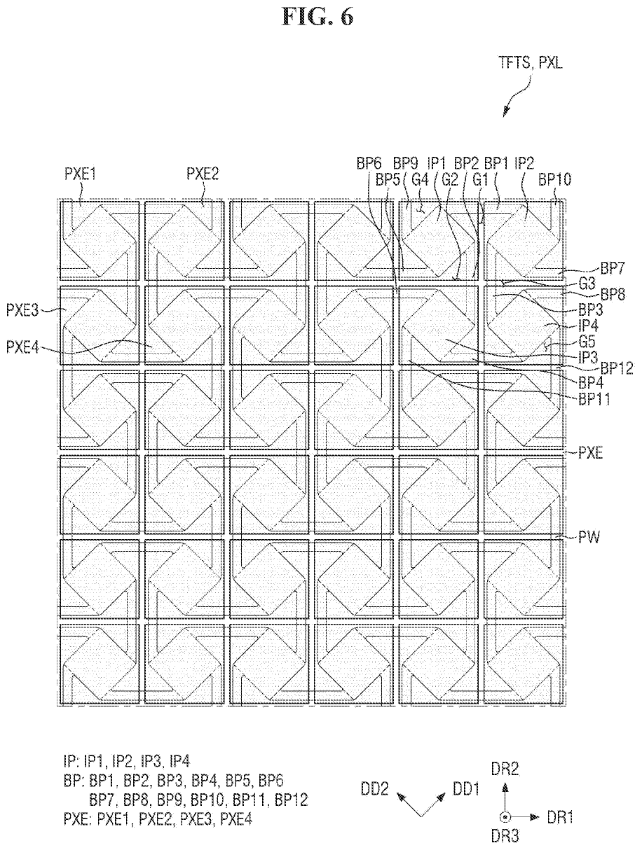

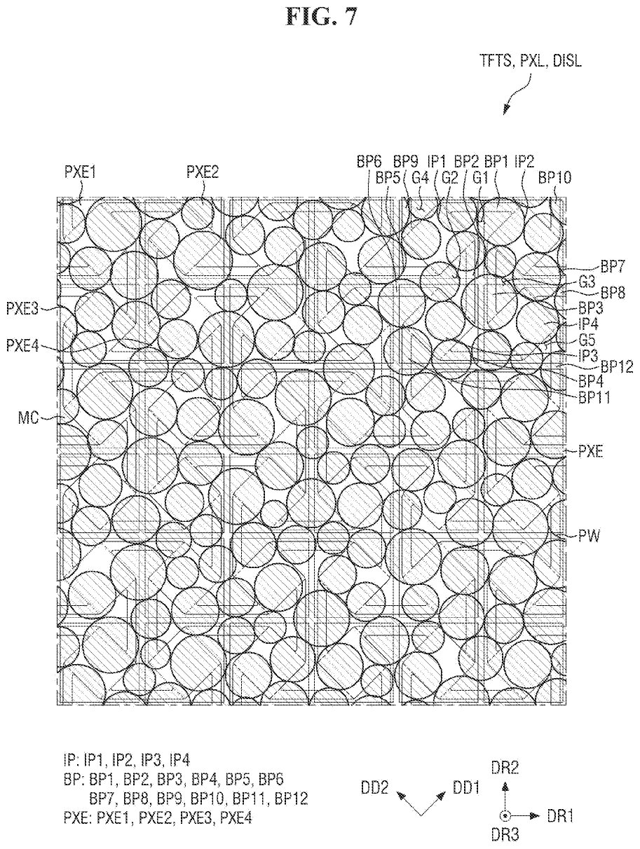

FIG. 4 is an exploded perspective view illustrating a portion of a display area of a stretchable display device according to one or more embodiments. FIG. 5A is a layout diagram illustrating an example of island patterns and bridge patterns of FIG. 4. FIG. 5B is an enlarged layout diagram illustrating in detail area A of FIG. 5A. FIG. 6 is a layout diagram illustrating an example of island patterns, bridge patterns, pixel electrodes, and partition walls of FIG. 4. FIG. 7 is a layout diagram illustrating an example of island patterns, bridge patterns, pixel electrodes, partition walls, and microcapsules of a display layer of FIG. 4.

Referring to FIGS. 4 to 7, the display device 10 according to one or more embodiments includes a thin-film transistor substrate TFTS, a pixel electrode layer PXL, a display layer DISL, and a common electrode CE.

The thin-film transistor substrate TFTS may include a plurality of island patterns IP and a plurality of bridge patterns BP to reduce the stretching stress applied to the thin-film transistor substrate TFTS in the stretching direction when the display device 10 is stretched.

Each of the plurality of island patterns IP may have a rectangular, rhombus, or square planar shape. Each of the plurality of island patterns IP may include a first side and a second side extending in a first diagonal direction DD1 that is a direction between the first direction DR1 and the second direction DR2, and a third side and a fourth side extending in a second diagonal direction DD2 that is orthogonal to the first diagonal direction DD1. Each of the plurality of island patterns IP may be connected to four bridge patterns BP. For example, each of the plurality of island patterns IP may be respectively connected to the bridge pattern BP at each vertex.

The plurality of island patterns IP may include a first island pattern IP1, a second island pattern IP2, a third island pattern IP3, and a fourth island pattern IP4. The first island pattern IP1, the second island pattern IP2, the third island pattern IP3, and the fourth island pattern IP4 may be defined as one island pattern group IPG.

The first island pattern IP1 and the second island pattern IP2 may be located adjacent to each other in the first direction DR1, and the third island pattern IP3 and the fourth island pattern IP4 may be located adjacent to each other in the first direction DR1. The first island pattern IP1 and the third island pattern IP3 may be located adjacent to each other in the second direction DR2, and the second island pattern IP2 and the fourth island pattern IP4 may be located adjacent to each other in the second direction DR2.

The plurality of bridge patterns BP may include first to twelfth bridge patterns BP1 to BP12. The plurality of bridge patterns BP may extend in the first direction DR1 or the second direction DR2.

Each of the first bridge pattern BP1, the second bridge pattern BP2, the third bridge pattern BP3, and the fourth bridge pattern BP4 refers to a pattern connecting adjacent island patterns in the first direction DR1 or the second direction DR2 in the island pattern group IPG. The first bridge pattern BP1 may connect the first island pattern IP1 and the second island pattern IP2 of the island pattern group IPG. The second bridge pattern BP2 may connect the first island pattern IP1 and the third island pattern IP3 of the island pattern group IPG. The third bridge pattern BP3 may connect the second island pattern IP2 and the fourth island pattern IP4 of the island pattern group IPG. The fourth bridge pattern BP4 may connect the third island pattern IP3 and the fourth island pattern IP4 of the island pattern group IPG.

A fifth bridge pattern BP5, a sixth bridge pattern BP6, a seventh bridge pattern BP7, and an eighth bridge pattern BP8 refer to a pattern connecting island patterns of adjacent island pattern group IPG in the first direction DR1. The fifth bridge pattern BP5 may be connected to the first island pattern IP1 of the island pattern group IPG, and to the second island pattern IP2 of the other island pattern group IPG adjacent thereto in the first direction DR1 (e.g., the left side). The sixth bridge pattern BP6 may be connected to the third island pattern IP3 of the island pattern group IPG, and to the fourth island pattern IP4 of the other island pattern group IPG adjacent thereto in the first direction DR1 (e.g., the left side). The seventh bridge pattern BP7 may be connected to the second island pattern IP2 of the island pattern group IPG, and to the first island pattern IP1 of another island pattern group IPG adjacent thereto in the first direction DR1 (e.g., the right side). The eighth bridge pattern BP8 may be connected to the fourth island pattern IP4 of the island pattern group IPG, and to the third island pattern IP3 of the other island pattern group IPG adjacent thereto in the first direction DR1 (e.g., the right side).

A ninth bridge pattern BP9, a tenth bridge pattern BP10, an eleventh bridge pattern BP11, and a twelfth bridge pattern BP12 refer to a pattern for connecting island patterns of adjacent island pattern groups IPGs in the second direction DR2. The ninth bridge pattern BP9 may be connected to the first island pattern IP1 of the island pattern group IPG, and to the third island pattern IP3 of another island pattern group IPG adjacent thereto in the second direction DR2 (e.g., the upper side). The tenth bridge pattern BP10 may be connected to the second island pattern IP2 of the island pattern group IPG, and to the fourth island pattern IP4 of the other island pattern group IPG adjacent thereto in the second direction DR2 (e.g., the upper side). The eleventh bridge pattern BP11 may be connected to the third island pattern IP3 of the island pattern group IPG, and to the first island pattern IP1 of yet another island pattern group IPG adjacent thereto in the second direction DR2 (e.g., the lower side). The twelfth bridge pattern BP12 may be connected to the fourth island pattern IP4 of the island pattern group IPG, and to the second island pattern IP2 of the other island pattern group IPG adjacent thereto in the second direction DR2 (e.g., the lower side).

First to fifth gaps G1 to G5 may exist in the island pattern group IPG.

The first gap G1 may be defined by the first island pattern IP1, the first bridge pattern BP1, the second island pattern IP2, the third bridge pattern BP3, the fourth island pattern IP4, the fourth bridge pattern BP4, the third island pattern IP3, and the second bridge pattern BP2.

The second gap G2 may be defined by the fifth bridge pattern BP5, the first island pattern IP1, the second bridge pattern BP2, the third island pattern IP3, and the sixth bridge pattern BP6. The third gap G3 may be defined by the seventh bridge pattern BP7, the second island pattern IP2, the third bridge pattern BP3, the fourth island pattern IP4, and the eighth bridge pattern BP8. The second gap G2 of the island pattern group IPG may be connected to the third gap G3 of another island pattern group IPG adjacent in the first direction DR1 (e.g., the left side). The third gap G3 of the island pattern group IPG may be connected to the second gap G2 of another island pattern group IPG adjacent in the first direction DR1 (e.g., the right side).

The fourth gap G4 may be defined by the ninth bridge pattern BP9, the first island pattern IP1, the first bridge pattern BP1, the second island pattern IP2, and the tenth bridge pattern BP10. The fifth gap G5 may be defined by the eleventh bridge pattern BP11, the third island pattern IP3, the fourth bridge pattern BP4, the fourth island pattern IP4, and the twelfth bridge pattern BP12. The fourth gap G4 of the island pattern group IPG may be connected to the fifth gap G5 of another island pattern group IPG adjacent in the second direction DR2 (e.g., the upper side). The fifth gap G5 of the island pattern group IPG may be connected to the fourth gap G4 of another island pattern group IPG adjacent in the second direction DR2 (e.g., the lower side).

As such, the display area DA may be suitably stretched in the first direction DR1 and the second direction DR2 due to the gaps G1 to G5 defined by the plurality of island patterns IP and the plurality of bridge patterns BP. Also, the display area DA includes the plurality of island patterns IP, the plurality of bridge patterns BP, and a plurality of gaps G1 to G5, but the non-display area NDA does not include the plurality of island patterns IP, the plurality of bridge patterns BP, and the plurality of gaps G1 to G5. Therefore, when the display device 10 is stretched, the stretch ratio of the display area DA may be higher than that of the non-display area NDA.

At least one thin-film transistor TFT, a storage capacitor CST, scan lines SL, data lines DL, and a storage line STL may be located in each of the plurality of island patterns IP.

The thin-film transistor TFT may include a gate electrode GE, an active layer ACT, a source electrode SE, and a drain electrode DE. The gate electrode GE is integrally formed with the scan line SL, and may be an area protruding from the scan line SL. The active layer ACT may be located to overlap the gate electrode GE. The source electrode SE is integrally formed with the data line DL and may be an area protruding from the data line DL. The drain electrode DE may be located to be spaced apart from the source electrode SE. A portion of the source electrode SE and a portion of the drain electrode DE may overlap the active layer ACT.

The storage capacitor CST may include a first capacitor electrode CSTE1 and a second capacitor electrode CSTE2, and may serve to maintain the voltage of the pixel electrode PXE connected to a second capacitor electrode CSTE2. The first capacitor electrode CSTE1 may be connected to the storage line STL to receive a storage voltage. The second capacitor electrode CSTE2 may be connected to the drain electrode DE. The first capacitor electrode CSTE1 and the second capacitor electrode CSTE2 may overlap each other.

The scan line SL and the storage line STL may be located in, or may overlap, the fifth bridge pattern BP5, the first island pattern IP1, the first bridge pattern BP1, the second island pattern IP2, and the seventh bridge pattern BP7 in the island pattern group IPG. Also, the scan line SL and the storage line STL may be located in, or may overlap, the sixth bridge pattern BP6, the third island pattern IP3, the fourth bridge pattern BP4, the fourth island pattern IP4, and the eighth bridge pattern BP8 in the island pattern group IPG.

The data line DL may be located in, or may overlap, the ninth bridge pattern BP9, the first island pattern IP1, the second bridge pattern BP2, the third island pattern IP3, and the eleventh bridge pattern BP11 in the island pattern group IPG. Also, the data line DL may be located in the tenth bridge pattern BP10, the second island pattern IP2, the third bridge pattern BP3, the fourth island pattern IP4, and the twelfth bridge pattern BP12 in the island pattern group IPG.

The pixel electrode layer PXL is located on the thin-film transistor substrate TFTS. The pixel electrode layer PXL may include a plurality of pixel electrodes PXE. Each of the plurality of pixel electrodes PXE may have a rectangular or square planar shape.

Each of the plurality of pixel electrodes PXE may be located on any one of the plurality of island patterns IP. For convenience of description, the pixel electrode PXE located on the first island pattern IP1 is defined as a first pixel electrode PXE1, the pixel electrode PXE located on the second island pattern IP2 is defined as a second pixel electrode PXE2, the pixel electrode PXE located on the third island pattern IP3 is defined as a third pixel electrode PXE3, and the pixel electrode PXE located on the fourth island pattern IP4 is defined as a fourth pixel electrode PXE4 among the plurality of pixel electrodes PXE.

An area of each of the plurality of pixel electrodes PXE may be larger than an area of the island pattern IP on which it is located. For example, an area of the first pixel electrode PXE1 may be larger than an area of the first island pattern IP1, and an area of the second pixel electrode PXE2 may be larger than an area of the second island pattern IP2. An area of the third pixel electrode PXE3 may be larger than an area of the third island pattern IP3, and an area of the fourth pixel electrode PXE4 may be larger than an area of the fourth island pattern IP4.

In this case, the first pixel electrode PXE1 may not only completely cover the first island pattern IP1, but also may cover a portion of the first bridge pattern BP1, the second bridge pattern BP2, the fifth bridge pattern BP5, and the ninth bridge pattern BP9 connected to the first island pattern IP1. Also, the second pixel electrode PXE2 may not only completely cover the second island pattern IP2, but also may cover a portion of the first bridge pattern BP1, the third bridge pattern BP3, the seventh bridge pattern BP7, and the tenth bridge pattern BP10 connected to the second island pattern IP2. In addition, the third pixel electrode PXE3 may not only completely cover the third island pattern IP3, but also may cover a portion of the second bridge pattern BP2, the fourth bridge pattern BP4, the sixth bridge pattern BP6, and the eleventh bridge pattern BP11 connected to the third island pattern IP3. Also, the fourth pixel electrode PXE4 may not only completely cover the fourth island pattern IP4, but also may cover a portion of the third bridge pattern BP3, the fourth bridge pattern BP4, the eighth bridge pattern BP8, and the twelfth bridge pattern BP12 connected to the fourth island pattern IP4.

Each of the plurality of pixel electrodes PXE may be formed of a stretchable electrode including carbon nanotubes, carbon nanoballs, or silver nanowires to reduce or prevent the likelihood of cracking when the plurality of island patterns IP and the plurality of bridge patterns BP are elongated. Therefore, modulus of the plurality of pixel electrodes PXE may be greater than modulus of signal lines, such as scan lines SL, storage lines STL, and data lines DL.

Each of the plurality of pixel electrodes PXE may be connected to the second capacitor electrode CSTE2 through a plurality of pixel contact holes PCT. Therefore, each of the plurality of pixel electrodes PXE may receive the data voltage of the data line DL when the thin-film transistor TFT is turned-on.

A partition wall PW may be located between the plurality of pixel electrodes PXE. The partition wall PW may be a structure to reduce or prevent the likelihood of the pixel electrodes PXE adjacent to each other being short-circuited when the display device 10 is stretched. The partition wall PW is a stretchable organic film, and may be formed of a silicon-based organic film, which is an organic film having a high modulus, but the present disclosure is not limited thereto.

The partition wall PW may overlap the first to fourth bridge patterns BP1 to BP4 without overlapping the plurality of island patterns IP. The partition wall PW may overlap the first gap G1, the second gap G2, and the third gap G3.

The display layer DISL may be a microcapsule array (or an electronic ink microcapsule array) including a plurality of microcapsules MC. The sizes of the plurality of microcapsules MC may not be uniform. Each of the plurality of microcapsules MC may have a substantially spherical or sphere-like shape, and a diameter of each of the plurality of microcapsules MC may be about 30 μm to about 300 μm. One microcapsule MC among the plurality of microcapsules MC may overlap any one of the plurality of island patterns IP, the plurality of bridge patterns BP, and/or the plurality of gaps G1 to G5 in the island pattern group IPG. Each of the plurality of microcapsules MC may include gelatin as an

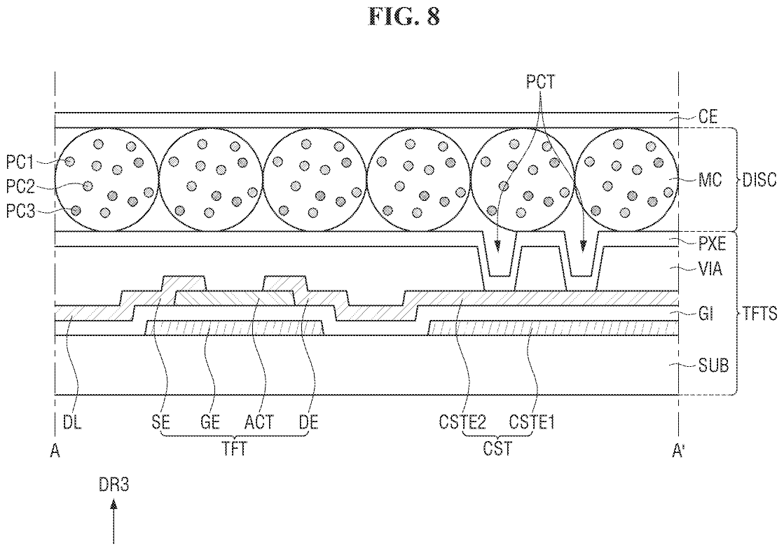

electrolyte to enable stretching. In this case, each of the plurality of microcapsules MC may be stretchable by about 5% to about 10%. A detailed description of the plurality of microcapsules MC will be described later with reference to FIG. 8.

The common electrode CE may be formed of a stretchable electrode including carbon nanotubes, carbon nanoballs, or silver nanowires to reduce or prevent the likelihood of cracking when the plurality of island patterns IP and the plurality of bridge patterns BP are elongated. Therefore, modulus of the common electrode CE may be greater than modulus of signal lines, such as scan lines SL, storage lines STL, and data lines DL.

As shown in FIGS. 5A, 5B, 6, and 7, the thin-film transistor substrate TFTS includes the plurality of island patterns IP and the plurality of bridge patterns BP to be stretchable, and at the same time, the plurality of pixel electrodes PXE and the common electrode CE are formed as stretchable electrodes including carbon nanotubes, carbon nanoballs, or silver nanowires. Also, the display layer DISL includes microcapsules MC containing stretchable gelatin as an electrolyte. Accordingly, because the thin-film transistor substrate TFTS, the plurality of pixel electrodes PXE, the display layer DISL, and the common electrode CE may all be stretched, the display area DA of the display device 10 may be suitably stretched by an external force.

FIG. 8 is a cross-sectional view illustrating an example of a display device taken along the line A-A′ of FIG. 5B.

Referring to FIG. 8, the thin-film transistor substrate TFTS may include a flexible substrate SUB, the thin-film transistor TFT, a gate insulating film GI, and a planarization film VIA.

The flexible substrate SUB may be made of an insulating material, such as a polymer resin. For example, the flexible substrate SUB may be made of an organic material, such as acrylic resin, epoxy resin, phenolic resin, polyamide resin, polyimide resin, etc. The flexible substrate SUB may be a stretchable flexible substrate. For example, the flexible substrate SUB may be made of polyimide.

A gate metal layer including the gate electrode GE of the thin-film transistor TFT, the first capacitor electrode CSTE1, the scan lines SL, and the storage lines STL may be located on the flexible substrate SUB. The gate metal layer may be formed as a single layer or multiple layers made of any one of molybdenum (Mo), aluminum (Al), chromium (Cr), gold (Au), titanium (Ti), nickel (Ni), neodymium (Nd) and/or copper (Cu) or an alloy thereof.

A gate-insulating layer GI may be located on the gate metal layer. The gate-insulating layer GI may include an inorganic insulating material, such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnOx). Zinc oxide (ZnOₓ) may be ZnO and/or ZnO₂.

The active layer ACT may be located on the gate-insulating layer GI. The active layer ACT may overlap the gate electrode GE in the third direction DR3. The active layer ACT may be made of polycrystalline silicon, single crystal silicon, low-temperature polycrystalline silicon, amorphous silicon, or an oxide semiconductor.

A data metal layer may be located on the gate-insulating layer GI and the active layer ACT. The source electrode SE, the drain electrode DE, and the second capacitor electrode CSTE2 may be located in the data metal layer. The source electrode SE and the drain electrode DE may be located apart from each other on the active layer ACT. The drain electrode DE and the second capacitor electrode CSTE2 may be integrally formed. The second capacitor electrode CSTE2 may overlap the first capacitor electrode CSTE1 in the third direction DR3.

A planarization layer VIA may be located on the data metal layer. The planarization film VIA may be made of an organic film, such as acryl resin, epoxy resin, phenolic resin, polyamide resin, polyimide resin, etc.

The plurality of pixel electrodes PXE may be located on the planarization layer VIA. Each of the plurality of pixel electrodes PXE may be connected to the second capacitor electrode CSTE2 through the plurality of pixel contact holes PCT penetrating the planarization layer VIA. The plurality of pixel electrodes PXE may be formed of a stretchable electrode including carbon nanotubes, carbon nanoballs, or silver nanowires.

The display layer DISL including the plurality of microcapsules MC may be located on the plurality of pixel electrodes PXE. The plurality of microcapsules MC may be located on each of the plurality of pixel electrodes PXE.

The common electrode CE may be located on the display layer DISL. The common electrode CE may be formed of a stretchable electrode including carbon nanotubes, carbon nanoballs, or silver nanowires.

Each of the plurality of microcapsules MC may include an electrolyte made of gelatin and at least two electrophoretic particles. For example, when each of the plurality of microcapsules MC includes a plurality of white particles PC1 and a plurality of black particles PC2, black and white may be expressed. While the plurality of white particles PC1 may be negatively charged, the plurality of black particles PC2 may be positively charged.

When a first data voltage corresponding to a positive voltage is applied to the pixel electrode PXE, the microcapsules MC display black, because the plurality of white particles PC1 move toward the pixel electrode PXE while the plurality of black particles PC2 move toward the common electrode CE. Also, when a second data voltage corresponding to a negative voltage is applied to the pixel electrode PXE, the microcapsules MC display white color, because the plurality of black particles PC2 move toward the pixel electrode PXE, while the plurality of white particles PC1 move toward the common electrode CE.

Alternatively, when each of the plurality of microcapsules MC includes the plurality of white particles PC1, the plurality of black particles PC2, and a plurality of color particles PC3, any one of white, black, and/or any one color may be expressed. The plurality of white particles PC1 are negatively charged, the plurality of black particles PC2 are positively charged, and the plurality of color particles PC3 are charged with a smaller positive value than the plurality of black particles PC2.

When the first data voltage corresponding to the positive voltage is applied to the pixel electrode PXE, the microcapsules MC display black, because the plurality of white particles PC1 move toward the pixel electrode PXE while the plurality of black particles PC2 and the plurality of color particles PC3 move toward the common electrode CE. The plurality of color particles PC3 move toward the common electrode CE, but may move more slowly than a plurality of black particles PC2 due to a lower charge strength than the plurality of black particles PC2.

When the second data voltage corresponding to the negative voltage is applied to the pixel electrode PXE, the microcapsules MC display white color, because the plurality of black particles PC2 and the plurality of color particles PC3 move toward the pixel electrode PXE while the plurality of white particles PC1 move toward the common electrode CE.

When a third data voltage corresponding to the positive voltage but lower than the first data voltage is applied to the pixel electrode PXE, the microcapsules MC display color, because the plurality of white particles PC1 move toward the pixel electrode PXE, and the plurality of color particles PC3 move toward the common electrode CE. In this case, because the third data voltage is not high enough to separate the plurality of black and white particles PC2 and PC1, the plurality of black particles PC2 may not move toward the common electrode CE.

In one or more embodiments, each of the plurality of microcapsules MC includes one type of the plurality of color particles PC3 in addition to the plurality of white particles PC1 and the plurality of black particles PC2, but the present disclosure is not limited thereto. Each of the plurality of microcapsules MC may include different types of color particles PC3 that are differently charged, and in this case, each of the plurality of microcapsules MC may display various colors other than white and black.

In addition, because the particles of each of the plurality of microcapsules MC have a bistable state in which they maintain their positions even when no voltage is applied any more, power consumption of the display device 10 may be reduced.

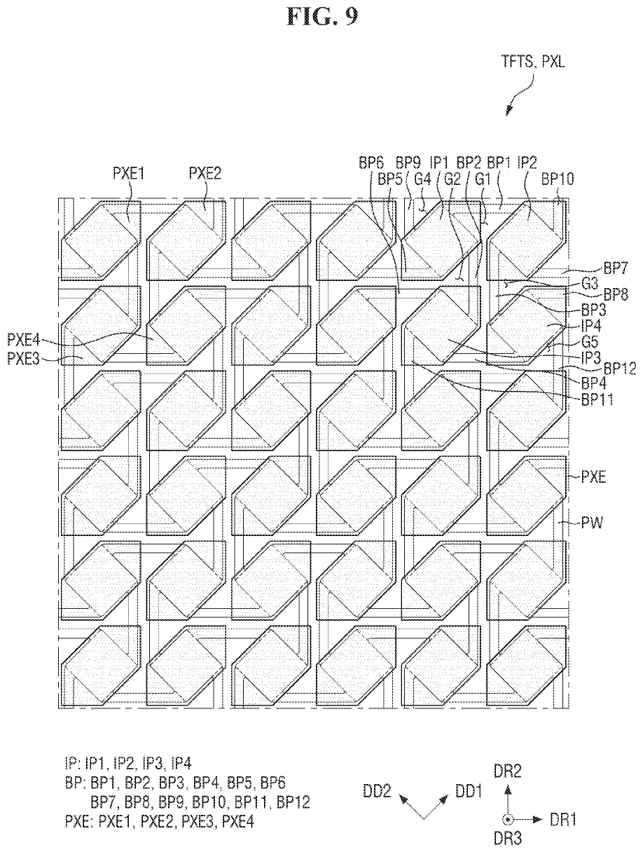

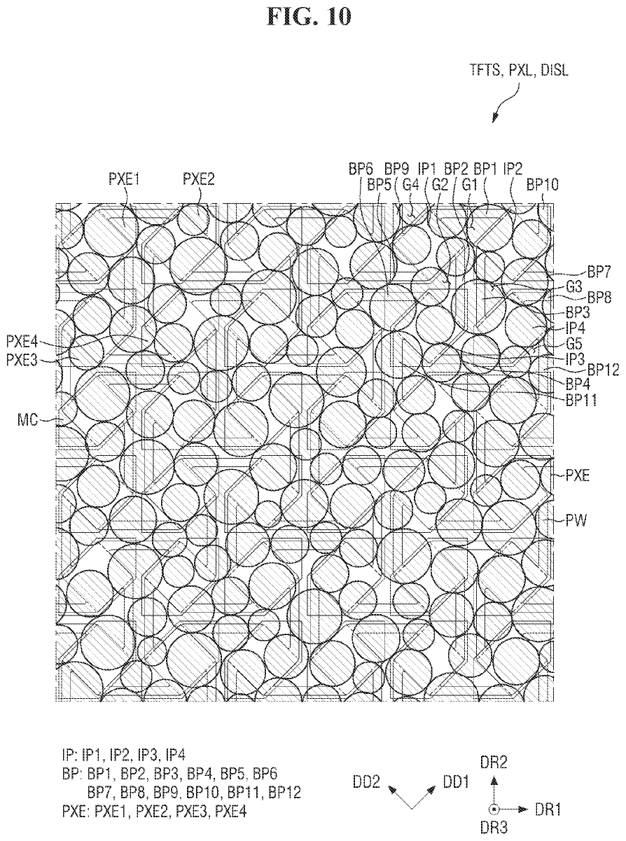

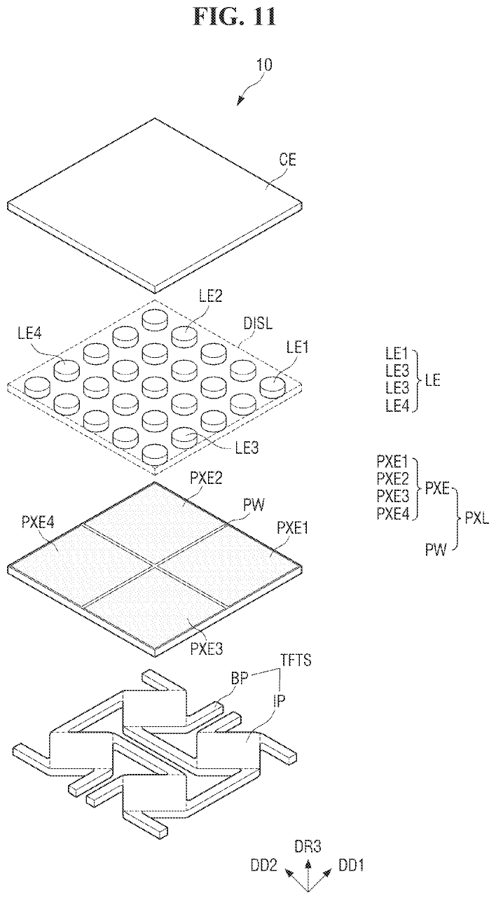

FIG. 9 is a layout diagram illustrating an example of island patterns, bridge patterns, and pixel electrodes of FIG. 4. FIG. 10 is a layout diagram illustrating an example of island patterns, bridge patterns, pixel electrodes, and microcapsules of a display layer of FIG. 9.

The embodiments of FIGS. 9 and 10 are different from the embodiments of FIGS. 6 and 7 in that each of the plurality of pixel electrodes PXE has a hexagonal planar shape. In FIGS. 9 and 10, descriptions overlapping those of the embodiments of FIGS. 6 and 7 will be omitted.

Referring to FIGS. 9 and 10, the first pixel electrode PXE1 may not only completely cover the first island pattern IP1, but may also partially cover the first bridge pattern BP1 and the fifth bridge pattern BP5 connected to the first island pattern IP1. The first pixel electrode PXE1 may not completely cover the second bridge pattern BP2 and the ninth bridge pattern BP9 connected to the first island pattern IP1.

The second pixel electrode PXE2 may not only completely cover the second island pattern IP2, but may also partially cover the third bridge pattern BP3 and the tenth bridge pattern BP10 connected to the second island pattern IP2. The second pixel electrode PXE2 may not completely cover the first bridge pattern BP1 and the seventh bridge pattern BP7 connected to the second island pattern IP2.

The third pixel electrode PXE3 may not only completely cover the third island pattern IP3, but also may partially cover the second bridge pattern BP2 and the eleventh bridge pattern BP11 connected to the third island pattern IP3. The third pixel electrode PXE3 may not completely cover the fourth bridge pattern BP4 and the sixth bridge pattern BP6 connected to the third island pattern IP3.

The fourth pixel electrode PXE4 may not only completely cover the fourth island pattern IP4, but may also partially cover the fourth bridge pattern BP4 and the eighth bridge pattern BP8 connected to the fourth island pattern IP4. The fourth pixel electrode PXE4 may not completely cover the third bridge pattern BP3 and the twelfth bridge pattern BP12 connected to the fourth island pattern IP4.

As shown in FIGS. 9 and 10, the bridge pattern BP connected to the island patterns IP adjacent to each other in the first direction DR1 or the second direction DR2 overlaps one pixel electrode PXE. Due to this, the distance between the pixel electrodes PXE adjacent to each other in the first direction DR1 or the second direction DR2 may increase. Therefore, when the display device 10 is stretched, it is possible to reduce or prevent the likelihood of the pixel electrodes PXE adjacent to each other being short-circuited even if the partition wall PW is not present.

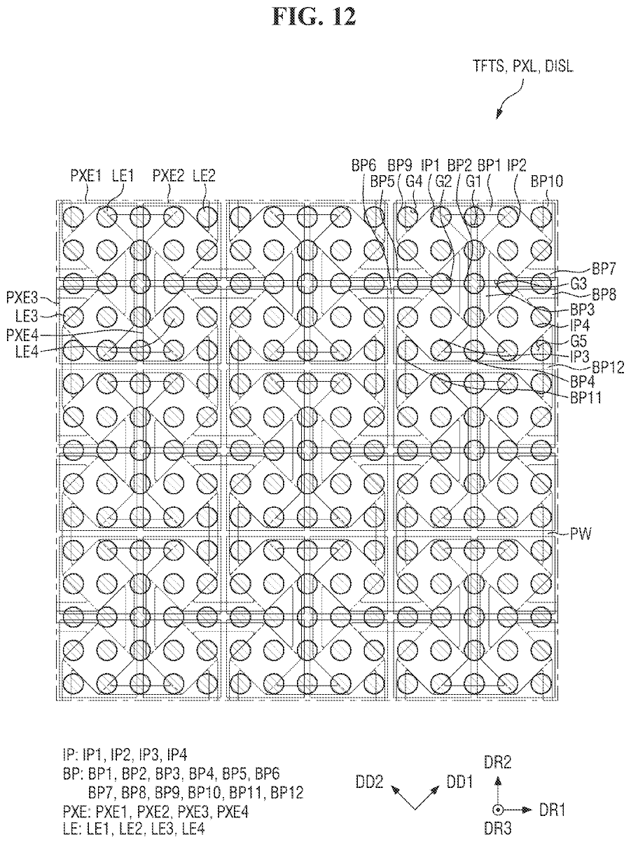

FIG. 11 is an exploded perspective view illustrating a stretchable display device according to one or more embodiments. FIG. 12 is a layout diagram illustrating an example of island patterns, bridge patterns, pixel electrodes, partition walls, and light-emitting devices of FIG. 11.

The embodiments of FIGS. 11 and 12 are different from the embodiments of FIGS. 4 and 7 in that the display layer DISL includes a plurality of light-emitting diode elements LE instead of the plurality of microcapsules MC. In FIGS. 11 and 12, descriptions overlapping those of the embodiments of FIGS. 4 and 7 will be omitted.

Referring to FIGS. 11 and 12, the display layer DISL may include the plurality of light-emitting diode elements LE. The plurality of light-emitting diode elements LE may be an inorganic light-emitting element including an anode electrode, a cathode electrode, and an inorganic semiconductor located between the anode electrode and the cathode electrode. The plurality of light-emitting diode elements LE may be micro light-emitting diode elements each having a length of several to hundreds of μm in a length in the first direction DR1, a length in the second direction DR2, and a length in the third direction DR3. Alternatively, the plurality of light-emitting diode elements LE may be nano light-emitting diode elements each having a length of several to several hundred nm in a first direction DR1, a second direction DR2, and a third direction DR3.

The plurality of light-emitting diode elements LE may include first light-emitting diode elements LE1, second light-emitting diode elements LE2, third light-emitting diode elements LE3, and fourth light-emitting diode elements LE4.

The first light-emitting diode elements LE1 are located on the first pixel electrode PXE1 and may emit a first light. The first light may be light of a red wavelength band. The red wavelength band may be about 600 nm to about 750 nm, but embodiments of the present disclosure are not limited thereto.

The second light-emitting diode elements LE2 are located on the second pixel electrode PXE2 and may emit a second light. The second light may be light of a green wavelength band. The green wavelength band may be about 480 nm to about 560 nm, but embodiments of the present disclosure are not limited thereto.

The third light-emitting diode elements LE3 are located on the third pixel electrode PXE3 and may emit a third light. The third light may be light of a blue wavelength band. The blue wavelength band may be about 370 nm to about 460 nm, but embodiments of the present disclosure are not limited thereto.

The fourth light-emitting diode elements LE4 are located on the fourth pixel electrode PXE4 and may emit any one of the first to third lights.

Any one of the first light-emitting diode elements LE1 may overlap any one of the first island pattern IP1, the first bridge pattern BP1, the second bridge pattern BP2, the fifth bridge pattern BP5, the ninth bridge pattern BP9, the first gap G1, the second gap G2, and/or the fourth gap G4. Any one of the second light-emitting diode elements LE2 may overlap any one of the second island pattern IP2, the first bridge pattern BP1, the third bridge pattern BP3, the seventh bridge pattern BP7, the tenth bridge pattern BP10, the first gap G1, the third gap G3, and/or the fourth gap G4.

Any one of the third light-emitting diode elements LE3 may overlap any one of the third island pattern IP3, the second bridge pattern BP2, the fourth bridge pattern BP4, the sixth bridge pattern BP6, the eleventh bridge pattern BP11, the first gap G1, the second gap G2, and/or the fifth gap G5. Any one of the fourth light-emitting diode elements LE4 may overlap any one of the fourth island pattern IP4, the third bridge pattern BP3, the fourth bridge pattern BP4, the eighth bridge pattern BP8, the twelfth bridge pattern BP12, the first gap G1, the third gap G3, and/or the fifth gap G5.

In FIG. 12, the first light-emitting diode elements LE1 emit the first light, the second light-emitting diode elements LE2 emit the second light, the third light-emitting diode elements LE3 emit the third light, the fourth light-emitting diode elements LE4 emit any one of the first light to the third light, but the present disclosure is not limited thereto. For example, the first light-emitting diode elements LE1, the second light-emitting diode elements LE2, the third light-emitting diode elements LE3, and the fourth light-emitting diode elements LE4 all may emit the third light. In this case, a first light conversion layer including first quantum dots for converting the third light into the first light may be located on the first light-emitting diode elements LE1, a second light conversion layer including second quantum dots for converting the third light into the second light may be located on the second light-emitting diode elements LE2, and a light transmitting layer through which the third light passes as it may be located on the third light-emitting diode elements LE3. Any one of the first light conversion layer, the second light conversion layer, and/or a light transmission layer may be located on the fourth light-emitting diode elements LE4.

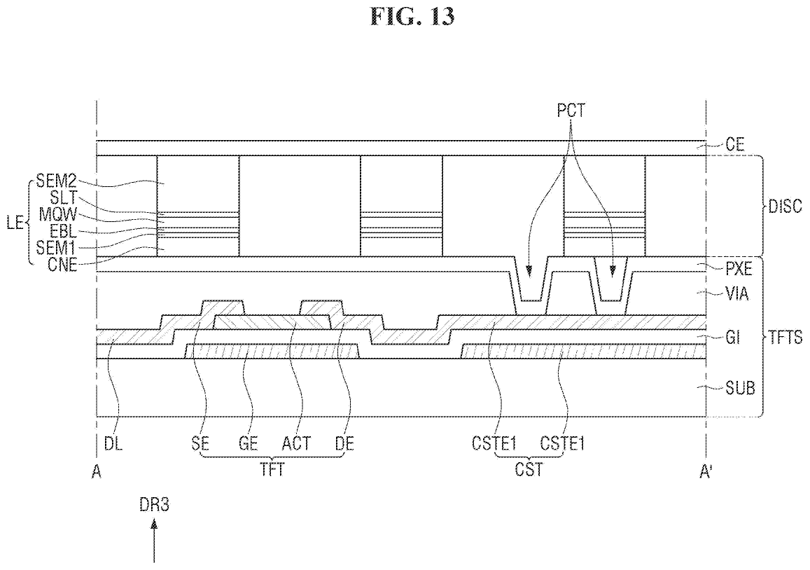

FIG. 13 is a cross-sectional view illustrating an example of a display device taken along the line A-A′ of FIG. 5B.

The embodiments of FIG. 13 is different from the embodiment of FIG. 8 in that the display layer DISL including the plurality of light-emitting diode elements LE instead of the plurality of microcapsules MC. In FIG. 13, a description overlapping with that of the embodiment of FIG. 8 will be omitted.

Referring to FIG. 13, each of the plurality of light-emitting diode elements LE may include a contact electrode CNE, a first semiconductor layer SEM1, an electron blocking layer EBL, an active layer MQW, a superlattice layer SLT, and a second semiconductor layer SEM2.

The contact electrode CNE may be located on the pixel electrode PXE. The contact electrode CNE and the pixel electrode PXE may be bonded to each other through a conductive adhesive member, such as an anisotropic conductive film (ACF) or an anisotropic conductive paste (ACP). Alternatively, the contact electrode CNE and the pixel electrode PXE may be bonded to each other through a soldering process. For example, the contact electrode CNE may include at least one of gold (Au), copper (Cu), aluminum (Al), and/or tin (Sn).

The first semiconductor layer SEMI may be located on the contact electrode CNE. The first semiconductor layer SEMI may be made of GaN doped with a p-type dopant, such as Mg, Zn, Ca, Se, or Ba.

The electron blocking layer EBL may be located on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. The electron blocking layer EBL may be omitted.

The active layer MQW may be located on the electron blocking layer EBL. The active layer MQW may emit light by combining electron-hole pairs according to an electric signal applied through the first semiconductor layer SEM1 and the second semiconductor layer SEM2.

The active layer MQW may include a material having a single or multiple quantum well structure. When the active layer MQW includes a material having a multi-quantum well structure, a plurality of well layers and barrier layers may be alternately stacked. In this case, the well layer may be formed of InGaN, and the barrier layer may be formed of GaN or AlGaN, but is not limited thereto. Alternatively, the active layer MQW may have a structure in which a semiconductor material having a large energy band gap and a semiconductor material having a small energy band gap are alternately stacked with each other. In addition, the active layer MQW may include other Group III to Group V semiconductor materials depending on the wavelength band of the emitted light.

When the active layer MQW includes InGaN, the color of emitted light may vary according to the content of indium (In). For example, as the content of indium (In) increases, the wavelength band of light emitted by the active layer MQW may move to a red wavelength band, and as the content of indium (In) decreases, the wavelength band of light emitted by the active layer MQW may move to a blue wavelength band. Therefore, the content of indium (In) in the active layer MQW of the first light-emitting diode element LE1 that emits the first light, which is light in the red wavelength band, may be higher than the content of indium (In) in the active layer MQW of the second light-emitting diode element LE2, and the content of indium (In) in the active layer MQW of the second light-emitting diode element LE2 may be higher than the content of indium (In) in the active layer MQW of the third light-emitting diode element LE3.

For example, the content of indium (In) in the active layer MQW of the first light-emitting diode element LE1 may be about 30 wt % to about 40 wt %, the content of indium (In) in the active layer MQW of the second light-emitting diode element LE2 may be about 20 wt % to about 30 wt %, and the content of indium (In) in the active layer MQW of the third light-emitting diode element LE3 may be about 10 wt % to about 20 wt %. In this case, the active layer MQW of the first light-emitting diode element LE1 may emit the first light, the active layer MQW of the second light-emitting diode element LE2 may emit the second light, and the active layer MQW of the third light-emitting diode element LE3 may emit the third light.

The superlattice layer SLT may be located on the active layer MQW. The superlattice layer SLT may be a layer to relieve stress between the second semiconductor layer SEM2 and the active layer MQW. For example, the superlattice layer SLT may be formed of InGaN or GaN. The superlattice layer SLT may be omitted.

The second semiconductor layer SEM2 may be located on the superlattice layer SLT. The second semiconductor layer SEM2 may be doped with a second conductivity type dopant, such as Si, Ge, SE, or Sn. For example, the second semiconductor layer SEM2 may be n-GaN doped with n-type Si.

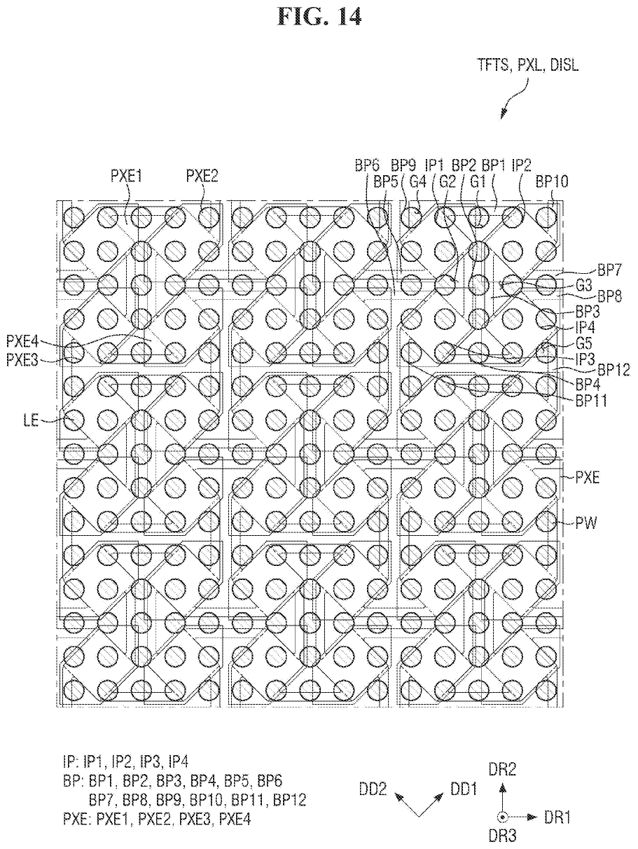

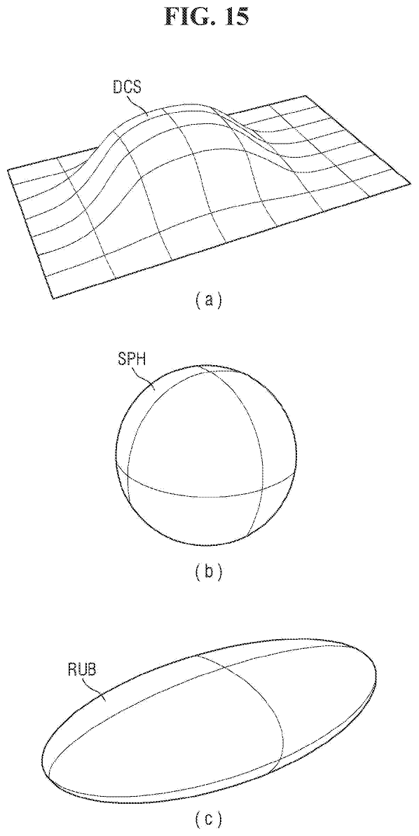

FIG. 14 is a layout diagram illustrating an example of island patterns, bridge patterns, pixel electrodes, and light-emitting elements of FIG. 11.

The embodiment of FIG. 14 is different from the embodiment of FIG. 7 in that each of the plurality of pixel electrodes PXE has a hexagonal planar shape. In FIG. 14, a description overlapping with that of the embodiment of FIG. 7 will be omitted.

Referring to FIG. 14, the first pixel electrode PXE1 may not only completely cover the first island pattern IP1, but may also partially cover the first bridge pattern BP1 and the fifth bridge pattern BP5 connected to the first island pattern IP1. The first pixel electrode PXE1 may not completely cover the second bridge pattern BP2 and the ninth bridge pattern BP9 connected to the first island pattern IP1.

The second pixel electrode PXE2 may not only completely cover the second island pattern IP2, but may also partially cover the third bridge pattern BP3 and the tenth bridge pattern BP10 connected to the second island pattern IP2. The second pixel electrode PXE2 may not completely cover the first bridge pattern BP1 and the seventh bridge pattern BP7 connected to the second island pattern IP2.

The third pixel electrode PXE3 may not only completely cover the third island pattern IP3, but may also partially cover the second bridge pattern BP2 and the eleventh bridge pattern BP11 connected to the third island pattern IP3. The third pixel electrode PXE3 may not completely cover the fourth bridge pattern BP4 and the sixth bridge pattern BP6 connected to the third island pattern IP3.

The fourth pixel electrode PXE4 may not only completely cover the fourth island pattern IP4, but may also partially cover the fourth bridge pattern BP4 and the eighth bridge pattern BP8 connected to the fourth island pattern IP4. The fourth pixel electrode PXE4 may not completely cover the third bridge pattern BP3 and the twelfth bridge pattern BP12 connected to the fourth island pattern IP4.

As shown in FIG. 14, the bridge pattern BP connected to the island patterns IP adjacent to each other in the first direction DR1 or the second direction DR2 overlaps one pixel electrode PXE. Due to this, the distance between the pixel electrodes PXE adjacent to each other in the first direction DR1 or the second direction DR2 may increase. Therefore, when the display device 10 is stretched, it is possible to reduce or prevent the likelihood of the pixel electrodes PXE adjacent to each other being short-circuited even if the partition wall PW is not present.

The (a) to (c) of FIG. 15 are views illustrating a curved surface to which a stretchable display device may be applicable according to one or more embodiments.

As described above, because the stretchable display device 10 according to one or more embodiments is stretchable, it may have a bent or folded shape. Therefore, the stretchable display device 10 according to one or more embodiments may have a double curved surface DCS having different curvatures in the first direction DR1 and the second direction DR2 as shown in FIG. 15(a). Also, the stretchable display device 10 according to one or more embodiments may have a sphere SPH shape as shown in FIG. 15(b). Also, the stretchable display device 10 according to one or more embodiments may have a rugby ball RUB shape as shown in FIG. 15(c). That is, the stretchable display device 10 according to one or more embodiments may have various bent or folded shapes.

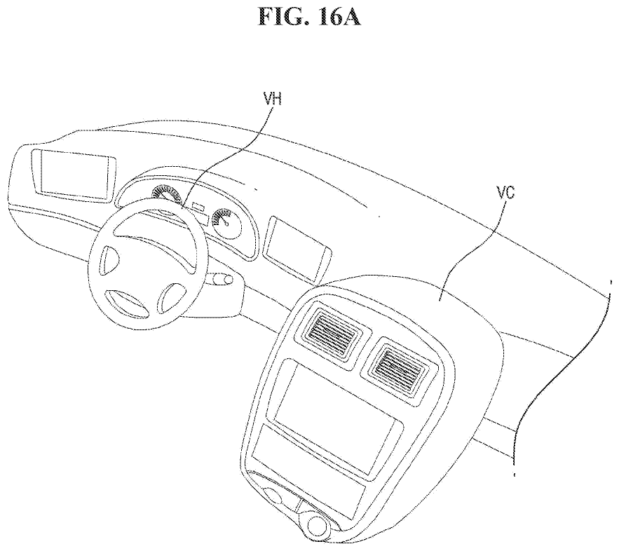

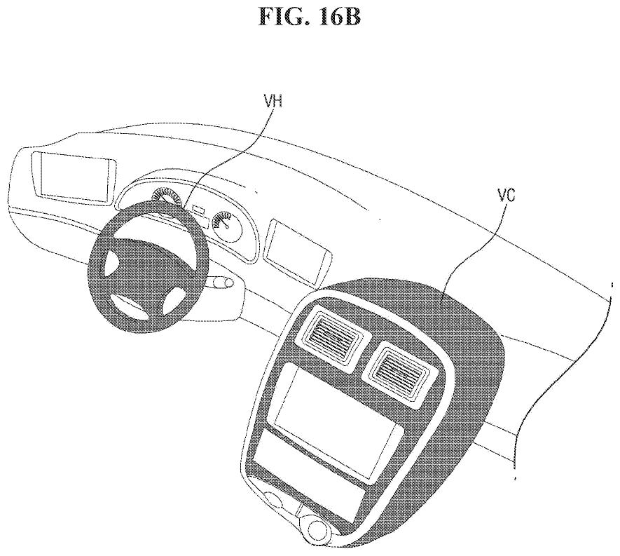

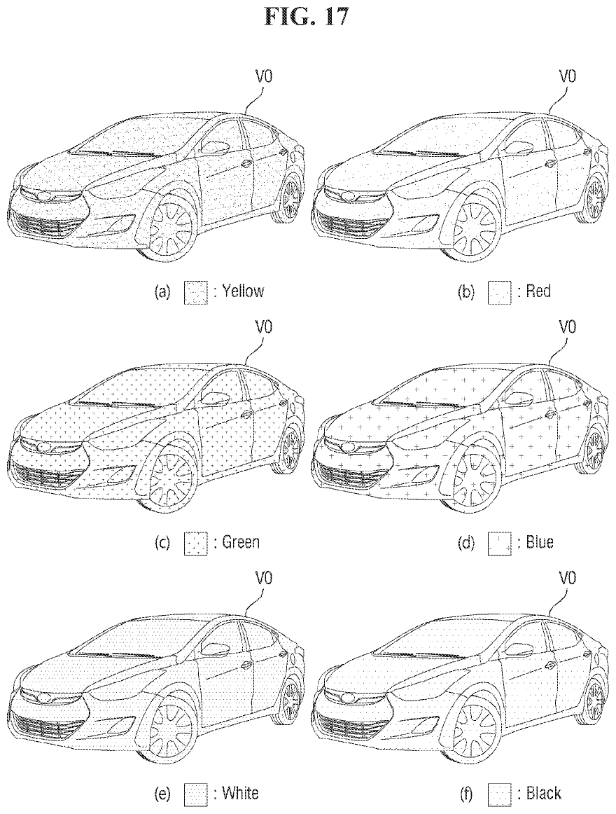

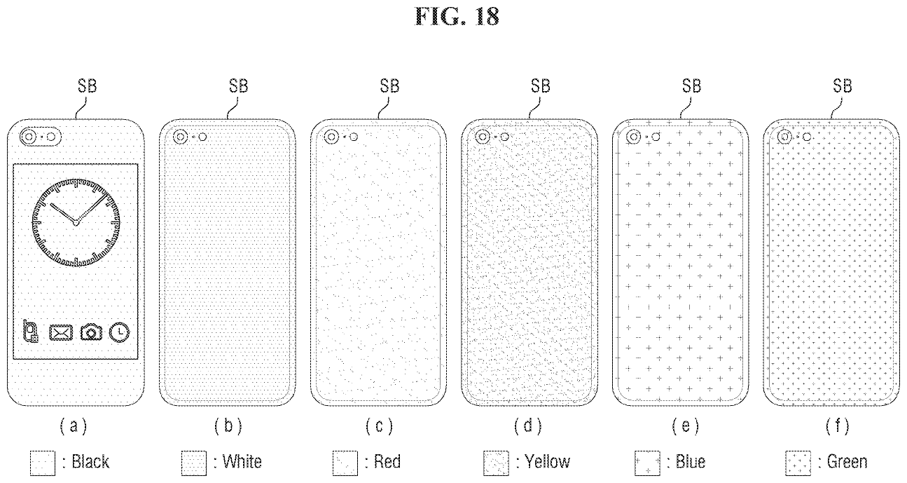

FIGS. 16A and 16B are views illustrating the interior of a vehicle to which a stretchable display device is applied according to one or more embodiments.

Referring to FIGS. 16A and 16B, the stretchable display device 10 according to one or more embodiments may be bent or folded in various ways, and thus may be applied to a steering wheel VH and a center fascia VC of a vehicle. In this case, the steering wheel VH and the center fascia VC of the vehicle to which the stretchable display device 10 is applied display white color as shown in FIG. 16A or display black color as shown in FIG. 16B by the microcapsules MC or the light-emitting diode elements LE of the display layer DISL. That is, by applying the stretchable display device 10 according to one or more embodiments to the interior of the vehicle, the interior color of the vehicle may be freely changed.

The (a) to (f) of FIG. 17 are views illustrating an exterior of a vehicle to which a stretchable display device is applied according to one or more embodiments.

Referring to (a) to (f) of FIG. 17, the stretchable display device 10 according to one or more embodiments may be bent or folded in various ways, and thus may be applied to the exterior VO of a vehicle. In this case, the exterior VO of the vehicle to which the stretchable display device 10 is applied display yellow color as shown in (a) of FIG. 17, display red color as shown in (b) of FIG. 17, or display green color as shown in (c) FIG. 17 by the microcapsules MC or the light-emitting diode elements LE of the display layer DISL. Alternatively, the exterior VO of the vehicle to which the stretchable display device 10 is applied is display blue color as shown in (d) FIG. 17, display white color as shown in (e) FIG. 17, or display black color as shown in (f) FIG. 17 by the microcapsules MC or the light-emitting diode elements LE of the display layer DISL. That is, by applying the stretchable display device 10 according to one or more embodiments to the exterior VO of the vehicle, the exterior color of the vehicle may be freely changed.

The (a) to (f) of FIG. 18 are views illustrating a rear surface of a smartphone to which a stretchable display device is applied according to one or more embodiments.

Referring to (a) to (f) of FIG. 18, the stretchable display device 10 according to one or more embodiments may be bent or folded in various ways, and thus may be applied to a rear surface SB of a smartphone. In this case, the rear surface SB of the smartphone to which the stretchable display device 10 is applied may display a clock, weather information, and a notification as shown in (a) of FIG. 18, display white color as shown in (b) of FIG. 18, or display red color as shown in (c) of FIG. 18 by the microcapsules MC or the light-emitting diode elements LE of the display layer DISL. Alternatively, the rear surface SB of the smartphone to which the stretchable display device 10 is applied may display yellow color as shown in (d) of FIG. 18, may display blue color as shown in (e) of FIG. 18, or may display green color as shown in (f) of FIG. 18 by the microcapsules MC or the light-emitting diode elements LE of the display layer DISL. That is, by applying the stretchable display device 10 according to one or more embodiments to the rear surface SB of the smartphone, display information or the color of the rear surface SB of the smartphone may be freely changed.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with functional equivalents thereof to be included therein.

What is claimed is:

1. A display device comprising:
a substrate comprising a first island pattern, a second island pattern, and a bridge pattern connecting the first island pattern and the second island pattern;
a first pixel electrode above the first island pattern, and having an area that is greater than an area of the first island pattern;
a second pixel electrode above the second island pattern;
a display layer above the first pixel electrode and the second pixel electrode, and configured to display an image; and
a common electrode above the display layer.

2. The display device of claim 1, wherein the first pixel electrode is above a portion of the bridge pattern.

3. The display device of claim 2, wherein the second pixel electrode is above another portion of the bridge pattern.

4. The display device of claim 1, wherein the first pixel electrode, the second pixel electrode, and the common electrode comprise carbon nanotubes, carbon nanoballs, or silver nanowires.

5. The display device of claim 1, further comprising a partition wall between the first pixel electrode and the second pixel electrode.

6. The display device of claim 5, wherein the partition wall overlaps the bridge pattern, and does not overlap the first pixel electrode and the second pixel electrode.

7. The display device of claim 1, wherein the first pixel electrode overlaps the bridge pattern, and the second pixel electrode does not overlap the bridge pattern.

8. The display device of claim 7, wherein each of the first pixel electrode and the second pixel electrode has a hexagonal shape in plan view.

9. The display device of claim 1, wherein the display layer comprises microcapsules comprising at least two electrophoretic particles, some of the microcapsules being above the first pixel electrode, and others of the microcapsules being above the second pixel electrode.

10. The display device of claim 9, wherein at least one of the some of the microcapsules overlaps the first island pattern or the bridge pattern.

11. The display device of claim 10, wherein at least one of the others of the microcapsules overlaps the second island pattern or the bridge pattern.

12. The display device of claim 1, wherein the display layer comprises light-emitting diode elements, some of the light-emitting diode elements being above the first pixel electrode, and others of the light-emitting diode elements being above the second pixel electrode.

13. The display device of claim 12, wherein at least one of the some of the light-emitting diode elements overlaps the first island pattern or the bridge pattern.

14. The display device of claim 13, wherein at least one of the others of the light-emitting diode elements overlaps the second island pattern or the bridge pattern.

15. A display device comprising:
a substrate comprising island patterns, and a bridge pattern connecting adjacent ones of the island patterns that are adjacent to each other in a first direction;
a pixel electrode above one of the island patterns;
a display layer above the pixel electrode, and configured to display an image; and
a common electrode above the display layer, and comprising a same material as the pixel electrode.

16. The display device of claim 15, wherein the display layer comprises microcapsules above the pixel electrode, and comprising at least two electrophoretic particles.

17. The display device of claim 15, wherein the display layer comprises light-emitting diode elements,
wherein a first electrode of any one of the light-emitting diode elements is connected to the pixel electrode, and
wherein a second electrode of each of the light-emitting diode elements is connected to the common electrode.

18. The display device of claim 15, wherein an area of the pixel electrode is larger than an area of the one of the island patterns.

19. The display device of claim 15, further comprising a signal line above the island patterns and the bridge pattern, and having a modulus that is less than a modulus of the pixel electrode.

20. The display device of claim 15, further comprising a signal line above the island patterns and the bridge pattern, and having a modulus that is less than a modulus of the common electrode.
